(19) United States
(12) Patent Application Publication
(10) Pub. No.: US 2025/0048895 A1
(43) Pub. Date: Feb. 6, 2025

(54) ORGANIC LIGHT-EMITTING DISPLAY PANEL AND DISPLAY DEVICE

(71) Applicant: WUHAN CHINA STAR OPTOELECTRONICS SEMICONDUCTOR DISPLAY TECHNOLOGY CO., LTD., Wuhan (CN)

(72) Inventors: Jiaxu Yao, Wuhan (CN); Kan Wang, Wuhan (CN); Jing Huang, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 17/296,193

(22) PCT Filed: Apr. 6, 2021
(86) PCT No.: PCT/CN2021/085603

§ 371 Date: May 31, 2024

(30) Foreign Application Priority Data
Mar. 11, 2021 (CN) 202110266495.2

(51) Int. Cl. H10K 59/80; H10K 59/122; H10K 59/40

(52) U.S. Cl. CPC H10K 59/879; H10K 59/122; H10K 59/8792; H10K 59/40

(57) ABSTRACT

An organic light-emitting display panel includes a pixel definition layer including a plurality of pixel openings, a black matrix layer including a plurality of first through holes and a light-shielding portion surrounding the first through holes, a first organic film layer filled at least in the first through holes and allowing for formation of a second through hole in each of the first through holes, an organic planarization layer covering the black matrix layer and the first organic film layer and filled in each of the second through holes, and a color filter layer covering the organic planarization layer, so that a light loss inside the display panel can be reduced, and transmittance can be increased.

### FIELD OF INVENTION

The present invention relates to a technical field of displays, and particularly to an organic light-emitting display panel and a display device.

### RELATED ART

Currently, organic light-emitting diode (OLED) mobile phone products are developing in a way of large size, high refresh rates, and high brightness. However, in the absence of a leapfrog breakthrough in battery technologies, markets have put forward higher requirements for power consumption of OLED products.

Polarizers (POL) can effectively reduce reflectivity of panels under strong light, but a light loss of nearly 58% is inevitable, which greatly increases a service life burden to OLEDs. In addition, the polarizers are known for relatively large thickness and brittle material, and thus are not beneficial to development of dynamic bending products. Therefore, how to improve light output efficiency of OLED devices has become a developing direction of low power consumption of OLED products in the future.

### SUMMARY OF INVENTION

### Technical Problems

An object of an embodiment of the present invention is to provide an organic light-emitting display panel and a display device to overcome a problem of a light loss arising from the use of polarizers in current organic light-emitting display panels. By using a multi-layer stacked structure including a black matrix layer, a first organic film layer, an organic planarization layer, and a color filter layer to replace the polarizers, a light loss inside a display panel is reduced, light transmittance inside the display panel is increased, and reflectivity of the display panel can be further reduced.

### Solutions of the Technical Problems

### Technical Solutions

In a first aspect, an embodiment of the present application provides an organic light-emitting display panel, comprising:
an array substrate comprising a pixel definition layer comprising a plurality of pixel openings;
a light-emitting device layer comprising a plurality of light-emitting units each disposed in one of the pixel openings;
a thin-film encapsulation layer covering the light-emitting device layer;
a black matrix layer located at a side of the thin-film encapsulation layer away from the array substrate and comprising a plurality of first through holes and a light-shielding portion surrounding the first through holes, wherein the first through holes have a one-to-one correspondence with the pixel openings;
a first organic film layer filled at least in the first through holes and allowing for formation of a second through hole in each of the first through holes;
an organic planarization layer covering the black matrix layer and the first organic film layer and filled in each of the second through holes, wherein the organic planarization layer has a refractive index greater than a refractive index of the first organic film layer; and
a color filter layer disposed on the organic planarization layer and comprising a plurality of color filter units having a one-to-one correspondence with the first through holes;
wherein an orthographic projection of each of the pixel openings and an orthographic projection of a corresponding one of the first through holes projected on a plane on which the array substate is located at least partially overlap each other, the orthographic projection of the corresponding one of the first through holes and an orthographic projection of a corresponding one of the color filter units projected on the plane on which the array substate is located at least partially overlap each other, each of the second through holes has an inverted trapezoidal shape in cross-section in a direction perpendicular to the array substrate, and an interface between the first organic film layer and the organic planarization layer in each of the second through holes is located at an angle between 40 degrees and 70 degrees with respect to a plane parallel with the array substate.

Optionally, in some embodiments of the present application, the orthographic projection of each of the pixel openings and the orthographic projections of the corresponding one of the first through holes and the corresponding one of the color filter units projected on the plane on which the array substate is located completely overlap each other.

Optionally, in some embodiments of the present application, the refractive index of the first organic film layer is between 1.2 and 1.5, and the refractive index of the organic planarization layer is between 1.7 and 2.0.

Optionally, in some embodiments of the present application, the first organic film layer covers a surface of the light-shielding portion away from the array substrate.

Optionally, in some embodiments of the present application, the first organic film layer has a thickness between 1 micron and 10 microns in a direction perpendicular to a side wall of the first through hole, and the organic planarization layer has a thickness between 5 microns and 30 microns on a side of the light-shielding portion away from the array substrate.

Optionally, in some embodiments of the present application, the organic light-emitting display panel further comprises:
a second organic film layer covering the color filter layer, and the second organic film layer has a refractive index between 1.3 and 1.5.

Optionally, in some embodiments of the present application, the organic light-emitting display panel further comprises a touch layer disposed between the thin-film encapsulation layer and the black matrix layer, wherein the touch layer comprises a touch electrode being grid-like in shape and having a plurality of grid openings, and the grid openings have a one-to-one correspondence with the pixel openings.

Optionally, in some embodiments of the present application, an orthographic projection of the touch electrode does not overlap the orthographic projection of any one of the pixel openings projected on the plane on which the array substrate is located.

In a second aspect, an embodiment of the present application provides an organic light-emitting display panel, comprising:
an array substrate comprising a pixel definition layer comprising a plurality of pixel openings;
a light-emitting device layer comprising a plurality of light-emitting units each disposed in one of the pixel openings;
a thin-film encapsulation layer covering the light-emitting device layer;
a black matrix layer located at a side of the thin-film encapsulation layer away from the array substrate and comprising a plurality of first through holes and a light-shielding portion surrounding the first through holes, wherein the first through holes have a one-to-one correspondence with the pixel openings;
a first organic film layer filled at least in the first through holes and allowing for formation of a second through hole in each of the first through holes;
an organic planarization layer covering the black matrix layer and the first organic film layer and filled in each of the second through holes, wherein the organic planarization layer has a refractive index greater than a refractive index of the first organic film layer; and
a color filter layer disposed on the organic planarization layer and comprising a plurality of color filter units having a one-to-one correspondence with the first through holes.

Optionally, in some embodiments of the present application, an orthographic projection of each of the pixel openings and an orthographic projection of a corresponding one of the first through holes projected on a plane on which the array substate is located at least partially overlap each other, and the orthographic projection of the corresponding one of the first through holes and an orthographic projection of a corresponding one of the color filter units projected on the plane on which the array substate is located at least partially overlap each other.

Optionally, in some embodiments of the present application, the orthographic projection of each of the pixel openings and the orthographic projections of the corresponding one of the first through holes and the corresponding one of the color filter units projected on the plane on which the array substate is located completely overlap each other.

Optionally, in some embodiments of the present application, the refractive index of the first organic film layer is between 1.2 and 1.5, and the refractive index of the organic planarization layer is between 1.7 and 2.0.

Optionally, in some embodiments of the present application, each of the second through holes has an inverted trapezoidal shape in cross-section in a direction perpendicular to the array substrate.

Optionally, in some embodiments of the present application, an interface between the first organic film layer and the organic planarization layer in each of the second through holes is located at an angle between 40 degrees and 70 degrees with respect to a plane parallel with the array substate.

Optionally, in some embodiments of the present application, the first organic film layer covers a surface of the light-shielding portion away from the array substrate.

Optionally, in some embodiments of the present application, the first organic film layer has a thickness between 1 micron and 10 microns in a direction perpendicular to a side wall of the first through hole, and the organic planarization layer has a thickness between 5 microns and 30 microns on a side of the light-shielding portion away from the array substrate.

Optionally, in some embodiments of the present application, the organic light-emitting display panel further comprises:
a second organic film layer covering the color filter layer, and the second organic film layer has a refractive index between 1.3 and 1.5.

Optionally, in some embodiments of the present application, the organic light-emitting display panel further comprises a touch layer disposed between the thin-film encapsulation layer and the black matrix layer, wherein the touch layer comprises a plurality of touch electrodes in a grid shape having a plurality of grid openings, and the grid openings have a one-to-one correspondence with the pixel openings.

Optionally, in some embodiments of the present application, an orthographic projection of each of the touch electrodes does not overlap the orthographic projection of any one of the pixel openings projected on the plane on which the array substrate is located.

In a third aspect, an embodiment of the present application further provides a display device comprising the display panel of any one of the organic light-emitting display panels.

### Advantageous Effect of Invention

### Beneficial Effect

The present application has advantageous effects as follows: compared to prior art, by using a multi-layer stacked structure including the black matrix layer, the first organic film layer, the organic planarization layer, and the color filter layer to replace a traditional polarizer, in comparison to a light loss of nearly 58% caused by the traditional polarizer, the multi-layer stacked structure of the embodiment of the present application can significantly reduce a light loss inside the display panel and increase light transmittance inside the display panel. In addition, the light-shielding portion of the black matrix layer can further absorb light from the outside, thereby reducing reflectivity of the display panel. Furthermore, by using a high refractive index material for the organic planarization layer and a low refractive index material for the first organic film layer, light emitted at large angles by a light-emitting element can be totally reflected by the interface between the organic planarization layer and the first organic film layer, so that scattered light is gathered, and a light scattering loss is reduced, thereby improving light output from a forward direction of a light-emitting area.

### BRIEF DESCRIPTION OF DRAWINGS

### Description of Drawings

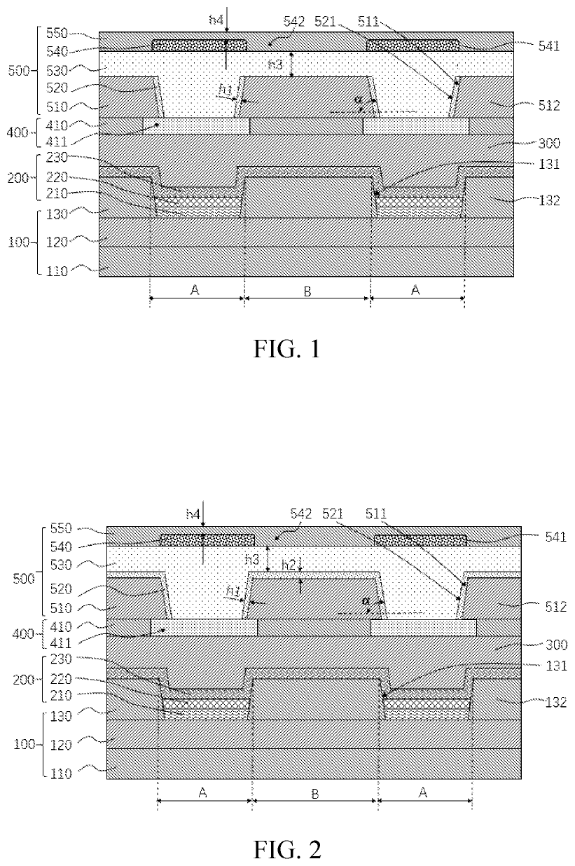

FIG. 1 is a schematic cross-sectional view of an organic light-emitting display panel provided by an embodiment of the present application.

FIG. 2 is a schematic cross-sectional view of an organic light-emitting display panel provided by another embodiment of the present application.

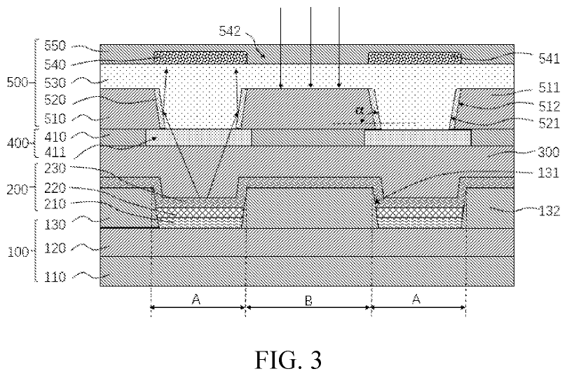

FIG. 3 a is a schematic view of an optical path principle of an organic light-emitting display panel provided by an embodiment of the present application.

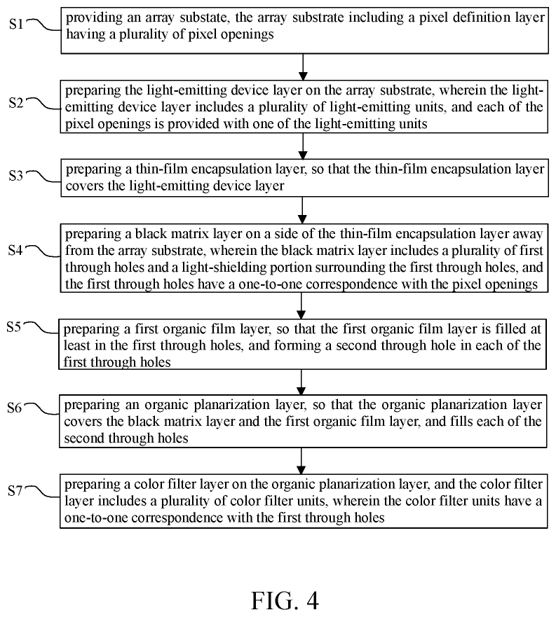

FIG. 4 is a flowchart of a method of manufacturing an organic light-emitting display panel provided by an embodiment of the present application.

### DETAILED DESCRIPTION OF EMBODIMENTS OF INVENTION

### Description of Preferred Embodiments

The embodiment of the present application provides an organic light-emitting display panel and a display device. Detailed descriptions are given below. It should be noted that the order of description in the following embodiments is not meant to limit the preferred order of the embodiments.

Please refer to FIGS. 1 to 3. An embodiment of the present application provides an organic light-emitting display panel including an array substrate 100, a light-emitting device layer, a thin-film encapsulation layer 300, and a multi-layer stacked structure 500. The multi-layer stacked structure 500 includes a black matrix layer 510, a first organic film layer 520, an organic planarization layer 530, and a color filter layer 540.

Please refer to FIGS. 1 and 2. The array substrate 100 includes a pixel definition layer 130. The pixel definition layer 130 includes a plurality of pixel openings 131 and a non-pixel opening area 132 surrounding the pixel openings 131. The pixel openings 131 are configured to define a plurality of light-emitting areas A. The non-pixel opening area 132 is configured to define a plurality of non-light-emitting areas B. It should be noted that although only the pixel definition layer 130 is described above for the array substrate 100, some necessary prior art structures are not described in detail. However, it can be understood that, in addition to the pixel definition layer 130, the array substrate 100 may also include other structures as required. For example, in this embodiment of the present application, the array substrate 100 further includes a base substrate 110 and a thin-film transistor functional layer 120, wherein the thin-film transistor functional layer 120 includes a plurality of thin-film transistors configured to drive the light-emitting device layer to emit light. Exemplarily, the pixel openings 131 are arranged in an array.

In one embodiment, each of the pixel openings 131 has an inverted trapezoidal shape in cross-section in a direction perpendicular to the array substrate 100. That is, an area of an upper opening of the pixel opening 131 (an opening away from the array substrate 100) is larger than an area of a lower opening of the pixel opening 131 (an opening close to the array substrate 100), such that the pixel opening 131 shrinks in a direction away from the array substrate 100 to a direction approaching the array substrate 100. Generally, the upper opening and the lower opening have a same shape. The pixel opening 131 is, but not limited to, circular or polygonal in shape in cross-section in a direction parallel with a plane on which the array substrate 100 is located. The polygonal shape includes, but not limited to, rhombuses, rectangles (including squares), octagons, etc.

Please refer to FIGS. 1 and 2. The light-emitting device layer includes a plurality of light-emitting units 200 each disposed in one of the pixel openings 131. The light-emitting units 200 are configured to form sub-pixels, such as red sub-pixels, green sub-pixels, and blue sub-pixels, so that the organic light-emitting display panel realizes a display function. Exemplarily, the light-emitting units 200 include an anode layer 210, an organic light-emitting diode (OLED) light-emitting layer 220, and a cathode layer 230. The anode layer 210 covers a bottom of each of the pixel openings 131, the OLED light-emitting layer 220 covers the anode layer 210 in each of the pixel openings 131, and the cathode layer 230 covers the OLED light-emitting layer 220.

Please refer to FIGS. 1 and 2. The thin-film encapsulation layer 300 covers the light-emitting device layer and is configured to encapsulate the light-emitting device layer, so as to block moisture and oxygen.

Please refer to FIGS. 1 and 2. The black matrix layer 510 is located at a side of the thin-film encapsulation layer 300 away from the array substrate 100 and includes a plurality of first through holes 511 and a light-shielding portion 512 surrounding the first through holes 511. The first through holes 511 have a one-to-one correspondence with the pixel openings 131. The first through holes 511 extend through the black matrix layer 510 in a direction of a thickness of the black matrix layer 510 (i.e., a direction perpendicular to the array substrate 100), so that light emitted by the light-emitting units 200 can pass through the black matrix layer 510, while the light-shielding portion 512 surrounding the first through holes 511 serves to shield and absorb light, which not only can prevent light mixing between adjacent ones of the light-emitting units 200, but also can absorb external light impinging on a display panel, thereby reducing reflectivity of the display panel. The black matrix layer 510 has a thickness, for example, between 1 micron and 10 microns (i.e., a thickness in a direction perpendicular to the plane on which the array substrate 100 is located).

In one embodiment, please refer to FIGS. 1 and 2. Each of the first through holes 511 has an inverted trapezoidal shape in cross-section in a direction perpendicular to the array substrate 100, that is, an area of an upper opening of the first through hole 511 (an opening away from the array substrate 100) is larger than an area of a lower opening of the first through hole 511 (an opening close to the array substrate 100), such that the first through hole 511 shrinks in a direction away from the array substrate 100 to a direction approaching the array substrate 100. Generally, the upper opening and the lower opening have a same shape. The first through hole 511 is, but not limited to, circular or polygonal in shape in cross-section in a direction parallel with the array substrate 100. The polygonal shape includes, but not limited to, rhombuses, rectangles (including squares), octagons, etc.

Please refer to FIGS. 1 and 2. In this embodiment, the first organic film layer 520 is filled at least in the first through holes 511 and forms a second through hole 521 in each of the first through holes 511. The first organic film layer 520 may be made of, for example, an optical clear adhesive. A material of the first organic film layer 520 includes, but not limited to, an organic material containing acrylic resin, epoxy resin, polyimide, polyethylene, and/or siloxane. In one embodiment, please refer to FIG. 1. The first organic film layer 520 is filled only in the first through holes 511 and forms the second through hole 521 in each of the first through holes 511, so that the first organic film layer 520 covers only a side wall of each of the first through holes 511 and surrounds the side wall of each of the first through holes 511 to form the second through hole 521. In this embodiment, in the first through hole 511, the first organic film layer 520 (i.e., the first organic film layer 520 covering the side wall of the first through hole 511) has a thickness h1 between 1 micron and 10 microns in a direction perpendicular to the side wall of the first through hole 511. It should be noted that the thickness h1 may be uniform thickness or non-uniform thickness. In another embodiment, please refer to FIG. 2. The first organic film layer 520 is filled in the first through hole 511 and forms the second through hole 521 in each of the first through holes 511. In addition, the first organic film layer 520 further covers a surface of the light-shielding portion 512 away from the array substrate 100, so that the first organic film layer 520 covers both the side wall of each of the first through holes 511 and the surface of the light-shielding portion 512 away from the light-emitting device layer, and the first organic film layer 520 surrounds to form the second through hole 521 in each of the first through holes 511. It should be noted that the second through holes 521 extend through the first organic film layer 520 in the direction perpendicular to the array substrate 100, so that the light emitted by the light-emitting units 200 can enter the second through holes 521 and pass through the second through holes 521. It can be understood that the side wall of the first through hole 511 is part of the light-shielding portion 512 located in the first through hole 511. By enabling the first organic film layer 520 to cover the light-shielding portion 512 in each of the first through holes 511, it not only can reduce the light entering the first through holes 511 from being absorbed by the light-shielding portion 512, but also can serve as a reflective interface for the light entering the first through hole 511 at large angles, thereby reducing a light loss inside the display panel. In this embodiment, in the first through hole 511, the first organic film layer 520 (i.e., the first organic film layer 520 covering the side wall of the first through hole 511) has the thickness h1 between 1 micron and 10 microns in the direction perpendicular to the side wall of the first through hole 511. The first organic film layer 520 has a thickness h2 (i.e., a thickness in the direction perpendicular to the plane on which the array substrate 100 is located) between 1 micron and 10 microns on a side of the light-shielding portion 512 away from the array substrate 100. It should be noted that the thickness h1 may be uniform thickness or non-uniform thickness.

Please refer to FIGS. 1 and 2. The organic planarization layer 530 covers the black matrix layer 510 and the first organic film layer 520, and fills up each of the second through holes 521. The organic planarization layer 530 is made of a material including, but not limited to, organic materials, such as acrylic resin, epoxy resin, polyimide, or polyethylene and/or siloxane, or a mixed material of any one of the aforementioned organic materials and zirconia, titania, and/or alumina particles. It should be noted that the material of the organic planarization layer 530 is different from the material of the first organic film layer 520. Please refer to FIG. 3. A light reflection interface (i.e., an interface between the organic planarization layer 530 and the first organic film layer 520 in each of the second through holes 521) can be provided by filling each of the second through holes 521 with the organic planarization layer 530. Light reflection occurs when light is incident on the interface between the organic planarization layer 530 and the first organic film layer 520 in each of the second through holes 521. In this manner, not only can light absorption by the light-shielding portion 512 be reduced, but scattered light emitted by the light-emitting units 200 can also be gathered through reflection, thereby reducing a light scattering loss and improving light output from a forward direction of a light-emitting area of the display panel. The organic planarization layer 530 has a thickness h3 between 5 microns and 30 microns on the side of the light-shielding portion 512 away from the array substrate 100 (i.e., a thickness in the direction perpendicular to the plane on which the array substrate 100 is located). It can be understood that the thickness h3 does not include a thickness of the organic planarization layer 530 with respect to the second through hole 521.

Please refer to FIG. 3. The organic planarization layer 530 has a refractive index greater than a refractive index of the first organic film layer 520. Making the refractive index of the organic planarization layer 530 greater than the refractive index of the first organic film layer 520 facilitates total reflection of light, so that the light emitted by the light-emitting units 200 at large angles can be totally reflected by the interface between the first organic film layer 520 and the organic planarization layer 530. In this manner, not only can the scattered light emitted by the light-emitting units 200 at large angles be gathered, but incident light at large angles can also be totally reflected without being refracted into the first organic film layer 520, thereby reducing a light loss and increasing a light output ratio. It can be understood that a critical angle of total reflection can be modified by adjusting the refractive index of the organic planarization layer 530, the refractive index of the first organic film layer 520, a refractive index difference between the organic planarization layer 530 and the first organic film layer 520, and/or an inclination angle of a side wall of the second through hole 521 (a as shown in FIGS. 1 and 2). In addition, in order to make the refractive index of the organic planarization layer 530 greater than the refractive index of the first organic film layer 520, the organic planarization layer 530 may be made of a high refractive index material, and the first organic film layer 520 may be made of a low refractive index material. In one embodiment, the refractive index of the first organic film layer 520 is between 1.2 and 1.5, and the refractive index of the organic planarization layer 530 is between 1.7 and 2.0.

Please refer to FIGS. 1 and 2. The color filter layer 540 is disposed on the organic planarization layer 530 and includes a plurality of color filter units 541. The color filter units 541 have a one-to-one correspondence with the first through holes 511. The color filter layer 540 further includes a plurality of third through holes 542 formed between adjacent ones of the color filter units 541 and dividing the color filter layer 540 into the color filter units 541. The color filter units include a red color filter unit, a green color filter unit, and a blue color filter unit, which are configured for filtering red light, green light, and blue light, respectively. Exemplarily, the color filter units 541 are, but are not limited to, circular or polygonal in shape in cross-section in the direction parallel with the array substrate 100. The polygonal shape includes, but not limited to, rhombuses, rectangles (including squares), octagons, etc. The color filter layer 540 has a thickness, for example, between 1 micron and 10 microns (i.e., a thickness in the direction perpendicular to the plane on which the array substrate 100 is located).

Please refer to FIGS. 1 and 2. An orthographic projection of each of the pixel openings 131 and an orthographic projection of a corresponding one of the first through holes 511 projected on the plane on which the array substate is located at least partially overlap each other. The orthographic projection of the corresponding one of the first through holes 511 and an orthographic projection of a corresponding one of the color filter units 541 projected on the plane on which the array substate 100 is located at least partially overlap each other.

It should be noted that instances that the orthographic projection of each of the pixel openings 131 and the orthographic projection of the corresponding one of the first through holes 511 projected on the plane on which the array substate 100 is located at least partially overlap each other include: (1) an instance that the orthographic projection of each of the pixel openings 131 and the orthographic projection of the corresponding one of the first through holes 511 projected on the plane on which the array substate 100 is located at least partially overlap each other at least includes: (a) the orthographic projection of each of the pixel openings 131 and the orthographic projection of the corresponding one of the first through holes 511 projected on the plane on which the array substate 100 is located overlap each other in such a way that any one of the orthographic projections does not completely fall within the other one of the orthographic projections. For example, a central axis of each of the pixel openings 131 (defined by the direction perpendicular to the plane on which the array substrate 100 is located) and a central axis of the corresponding one of the first through holes 511 (defined by the direction perpendicular to the plane on which the array substrate 100 is located) are staggered from each other, and the orthographic projections of the pixel opening 131 and the first through hole 511 partially fall within each other; (b) any one of the orthographic projection of each of the pixel openings 131 or the orthographic projection of the corresponding one of the first through holes 511 projected on the plane on which the array substate 100 is located completely falls within the orthographic projection of the other one. For example, the central axis of each of the pixel openings 131 (defined by the direction perpendicular to the plane on which the array substrate 100 is located) and the central axis of the corresponding one of the first through holes 511 (defined by the direction perpendicular to the plane on which the array substrate 100 is located) overlap each other, and the first through hole 511 is reduced or enlarged according to a certain ratio based on the corresponding pixel opening 131. As another example, the central axis of each of the pixel openings 131 (defined by the direction perpendicular to the plane on which the array substrate 100 is located) and the central axis of the corresponding one of the first through holes 511 (defined by the direction perpendicular to the plane on which the array substrate 100 is located) are staggered from each other, wherein the orthographic projection of the pixel opening 131 projected on the plane on which the array substrate 100 is located completely falls within the orthographic projection of the corresponding first through hole 511 projected on the plane on which the array substrate 100 is located; (2) the orthographic projection of each of the pixel openings 131 and the orthographic projection of the corresponding one of the first through holes 511 projected on the plane on which the array substate 100 is located completely overlap each other, such that the orthographic projections of the pixel opening 131 and the corresponding first through hole 511 projected on the plane on which the array substrate 100 is located are identical in shape and size.

It should also be noted that in this embodiment, instances that the orthographic projection of the first through hole 511 and the orthographic projection of the corresponding one of the color filter units 541 projected on the plane on which the array substate 100 is located at least partially overlap each other include: (1) an instance that the orthographic projection of the first through hole 511 and the orthographic projection of the corresponding one of the color filter units 541 projected on the plane on which the array substate 100 is located at least partially overlap each other at least includes: (a) the orthographic projection of the first through hole 511 and the orthographic projection of the corresponding one of the color filter units 541 projected on the plane on which the array substate 100 is located overlap each other in such a way that any one of the orthographic projections does not completely fall within the other one of the orthographic projections. For example, the central axis of the first through hole 511 (defined by the direction perpendicular to the plane on which the array substrate 100 is located) and a central axis of the corresponding one of the color filter units 541 (defined by the direction perpendicular to the plane on which the array substrate 100 is located) are staggered from each other, and the orthographic projections of the first through hole 511 and the color filter unit 541 partially fall within each other; (b) any one of the orthographic projection of the first through hole 511 or the orthographic projection of the corresponding one of the color filter units 541 projected on the plane on which the array substate 100 is located completely falls within the orthographic projection of the other one. For example, the central axis of the first through hole 511 (defined by the direction perpendicular to the plane on which the array substrate 100 is located) and the central axis of the corresponding one of the color filter units 541 (defined by the direction perpendicular to the plane on which the array substrate 100 is located) overlap each other, and the color filter unit 541 is reduced or enlarged according to a certain ratio based on the corresponding first through hole 511. As another example, the central axis of the first through hole 511 (defined by the direction perpendicular to the plane on which the array substrate 100 is located) and the central axis of the corresponding one of the color filter units 541 (defined by the direction perpendicular to the plane on which the array substrate 100 is located) are staggered from each other, wherein the orthographic projection of the first through hole 511 projected on the plane on which the array substrate 100 is located completely falls within the orthographic projection of the corresponding color filter unit 541 projected on the plane on which the array substrate 100 is located; (2) the orthographic projection of the first through hole 511 and the orthographic projection of the corresponding one of the color filter units 541 projected on the plane on which the array substate 100 is located completely overlap each other, such that the orthographic projections of the first through hole 511 and the corresponding color filter unit 541 projected on the plane on which the array substrate 100 is located are identical in shape and size.

It should also be noted that the orthographic projection mentioned in the embodiment of the present application refers to a projection perpendicular to the plane on which the array substrate 100 is located. The orthographic projection of the pixel opening 131 in the embodiment of the present application refers to a closed pattern formed by an orthographic projection of an outermost edge of the pixel opening 131 on the array substrate 100. Likewise, the orthographic projection of the first through hole 511 refers to a closed pattern formed by an orthographic projection of an outermost edge of the first through hole 511 on the array substrate 100, and the orthographic projection of the color filter unit 541 refers to a closed pattern formed by an orthographic projection of an outermost edge of the color filter unit 541 on the array substrate 100.

It should also be noted that in the embodiment of the present application, shapes of any two of the pixel opening 131, the first through hole 511, or the second through hole 521 may be same or different. Cross-sectional shapes of the color filter unit 541 and the first through hole 511 in a direction parallel with a plane on which the array substrate 100 is located may be same or different.

In one embodiment, please refer to FIGS. 1 and 2. The orthographic projection of each of the pixel openings 131 and the orthographic projections of the corresponding first through hole 511 and the corresponding color filter unit 541 on the plane on which the array substate 100 is located completely overlap one another, so that a greater amount of light from the light-emitting unit 200 can be injected into the second through hole 521, and a greater amount of light at large angles can be reflected by the interface between the first organic film layer 520 and the organic planarization layer 530 and can be emitted out after being filtered by the color filter unit 541, so that the display panel has a higher light output ratio.

By using the multi-layer stacked structure 500 including the black matrix layer 510, the first organic film layer 520, the organic planarization layer 530, and the color filter layer 540 to replace a polarizer, in comparison to a light loss of nearly 58% caused by the polarizer, the embodiment of the present application can significantly reduce the light loss inside the display panel and increase light transmittance inside the display panel, In addition, the light-shielding portion 512 of the black matrix layer 510 can further absorb light from the outside, thereby reducing the reflectivity of the display panel. Specifically, the first organic film layer 520 covering the light-shielding portion 512 of the second through hole 521 can reduce or prevent the light entering the first through hole 511 from being absorbed by the light-shielding portion 512. The first organic film layer 520 and the organic planarization layer 530 collectively form a structure similar to a microlens array in the first through holes 511, and the interface between the first organic film layer 520 and the organic planarization layer 530 can provide a reflective interface for the light at large angles entering the first through hole 511, so that the light is reflected by the interface, especially totally reflected. In this manner, the scattered light emitted by the light-emitting units 200 after reflection is gathered, and light output from the forward direction of the light-emitting area of the display panel is improved, thereby reducing the light loss due to the scattered light. The light-shielding portion 512 of the black matrix layer 510 can further absorb light from the outside, thereby reducing the reflectivity of the display panel. In addition, if the first organic film layer 520 only covers the side wall of the first through hole 511 and is not disposed over the surface of the light-shielding portion 512 away from the light-emitting device layer, not only can absorption of light from the outside by the light-shielding portion 512 of the black matrix layer 510 be increased, but a thickness of the multi-layer stacked structure 500 can also be thinner.

In one embodiment, please refer to FIGS. 1 and 2. The multi-layer stacked structure 500 of the embodiment of the present application further includes a second organic film layer 550 covering the color filter layer 540 and filling the third through holes 542. The second organic film layer 550 may serve to provide a planarization effect. A material of the second organic film layer 550 may be, for example, an optical clear adhesive. The material of the second organic film layer 550 includes, but not limited to, an organic material containing acrylic resin, epoxy resin, polyimide, polyethylene, and/or siloxane. The second organic film layer 550 has a refractive index between 1.3 and 1.5. The second organic film layer 550 has a thickness h4 between 5 microns and 30 microns on a side of the color filter layer 540 away from the array substrate 100 (i.e., a thickness in the direction perpendicular to the plane on which the array substrate 100 is located). It can be understood that the thickness h4 does not include part of the second organic film layer 550 filled in the third through hole 542. In one embodiment, please refer to FIGS. 1 and 2. The second through hole 521 is trapezoidal in shape in cross-section in the direction perpendicular to the array substrate 100. It can be understood that an area of an upper opening of the second through hole 521 (an opening away from the array substrate 100) is larger than an area of a lower opening of the second through hole 521 (an opening close to the array substrate 100), such that the second through hole 521 shrinks in a direction away from the array substrate 100 to a direction approaching the array substrate 100. Generally, the upper opening and the lower opening have a same shape. The second through hole 521 is, but not limited to, circular or polygonal in shape in cross-section in the direction parallel with the array substrate 100. The polygonal shape includes, but not limited to, rhombuses, rectangles (including squares), octagons, etc.

In one embodiment, please refer to FIGS. 1 and 2. an interface between the first organic film layer 520 and the organic planarization layer 530 in each of the second through holes 521 is located at an angle α between 40 degrees and 70 degrees with respect to a plane parallel with the array substate 100. It can be understood that the interface between the organic planarization layer 530 and the first organic film layer 520 is the side wall of the second through hole 521. The acute angle α formed by the interface between the first organic film layer 520 and the organic planarization layer 530 and the plane parallel with the array substate 100 can reflect the extent of inclination of the side wall of the second through hole 521. A greater amount of light at large angles emitted by the light-emitting units 200 can be totally reflected by the interface between the first organic film layer 520 and the organic planarization layer 530 by controlling the acute angle α between 40 degrees and 70 degrees formed by the interface between the first organic film layer 520 and the organic planarization layer 530 and the plane parallel with the array substate 100 in each of the second through holes 521, so that the organic light-emitting display panel has a higher light output ratio.

In one embodiment, a shape of the lower opening of the pixel opening 131 (an opening close to the array substrate 100), a shape of the lower opening of the first through hole 511 (an opening close to the array substrate 100), and a cross-sectional shape of the color filter unit 541 in a direction parallel with a plane on which the array substrate 100 is located are same, which may include, for example, but not limited to circular or polygonal, wherein the polygonal shape includes, but not limited to rhombuses, rectangles (including squares), octagons, etc. It should be noted that sizes of any two of the foregoing three shapes may be same or different, or shapes and sizes of the three may be completely the same. In addition, in some other embodiments, cross-sectional shapes of the lower openings of the pixel opening 131, the first through hole 511, and the color filter unit 541 in the direction parallel with the plane on which the array substrate 100 is located may also be different from each other.

In one embodiment, cross-sectional shapes of the pixel opening 131, the first through hole 511, and the color filter unit 541 in the direction parallel with the plane on which the array substrate 100 is located are same. Any cross-sectional shape of the pixel opening 131 in the direction parallel with the plane on which the array substrate 100 is located is same as each other (i.e., the upper opening and the lower opening are identical in shape). Any cross-sectional shape of the first through hole 511 in the direction parallel with the plane on which the array substrate 100 is located is same as each other (i.e., the upper opening and the lower opening are identical in shape). Any cross-sectional shape of the color filter unit 541 in the direction parallel with the plane on which the array substrate 100 is located is same as each other (i.e., the upper opening and the lower opening are identical in shape). It should be noted that cross-sections of the pixel opening 131, the first through hole 511, and the color filter unit 541 in the direction parallel with the plane on which the array substrate 100 is located may be same or different in size.

It should be noted that in the embodiment of the present application, the multi-layer stacked structure 500 is disposed on the side of the thin-film encapsulation layer 300 away from the array substrate 100, and there are other film layers provided between the thin-film encapsulation layer 300 and the multi-layer stacked structure 500, for example, such as film layers for touch functions. In one embodiment, please refer to FIGS. 1 and 2. The organic light-emitting display panel further includes a touch layer 400 disposed between the thin-film encapsulation layer 300 and the multi-layer stacked structure 500. Specifically, the touch layer 400 is disposed between the thin-film encapsulation layer 300 and the black matrix layer 510. The touch layer 400 is configured to implement a touch function and may have a structure adopting a known structure in prior art.

Exemplarily, the touch layer 400 includes a touch electrode 410. The touch electrode 410 is grid-like in shape and has a plurality of grid openings 411, and the grid openings 411 have a one-to-one correspondence with the pixel openings 131. An orthographic projection of the touch electrode 410 does not overlap the orthographic projection of any one of the pixel openings 131 projected on the plane on which the array substrate 100 is located, so that the touch electrode 410 bypasses the pixel openings 131 without hindering the light of the light-emitting units 200 from being emitted out of the touch layer 400. Exemplarily, an area of each of the grid openings 411 is larger than an area of the upper opening of the pixel opening 131 (an opening away from the array substrate 100), so that the light emitted by the light-emitting units 200 can pass through the touch layer 400 over the grid openings 411.

In the above-mentioned embodiments, the description of each embodiment has its own focus. For parts that are not described in detail in an embodiment, please refer to the relevant description of other embodiments.

Correspondingly, please refer to FIGS. 1 to 4. An embodiment of the present application further provides a preparation method of the organic light-emitting display panel, and the preparation method includes:

S1: providing an array substate 100, the array substrate 100 including a pixel definition layer 130 having a plurality of pixel openings 131. The pixel openings 131 are configured to define a plurality of light-emitting areas A, and a non-pixel opening area 132 is formed to define a plurality of non-light-emitting areas B.

Exemplarily, the array substrate 100 includes a base substrate 110, a thin-film transistor functional layer 120, and the pixel definition layer 130. The thin-film transistor functional layer 120 is formed on the base substrate 110 and includes a plurality of thin-film transistors for driving the light-emitting device layer to emit light. The pixel definition layer 130 is formed on thin-film transistor functional layer 120 and includes the pixel openings 131 and the non-pixel opening area 132 surrounding the pixel openings 131. The pixel openings 131 are arranged in an array. It should be noted that a method of preparing the array substrate 100 can be a known method in prior art and is not specifically limited by the embodiment of the present application.

S2: preparing the light-emitting device layer on the array substrate 100, wherein the light-emitting device layer includes a plurality of light-emitting units 200, and each of the pixel openings 131 is provided with one of the light-emitting units 200.

Exemplarily, step S2 includes: preparing an anode layer 210 in each of the pixel openings 131, and making the anode layer 210 cover a bottom of the pixel opening 131; preparing an OLED light-emitting layer 220 on the anode layer 210, and making the OLED light-emitting layer 220 cover the anode layer 210; and preparing a cathode layer 230, and making the cathode layer 230 cover the OLED light-emitting layer 220 and the pixel definition layer 130.

S3: preparing a thin-film encapsulation layer 300, so that the thin-film encapsulation layer 300 covers the light-emitting device layer. It should be noted that a method of preparing the thin-film encapsulation layer 300 can be a known method in prior art and is not specifically limited by the embodiment of the present application.

In one embodiment, after step S3, it may further include preparing a touch layer 400 on the thin-film encapsulation layer 300. It should be noted that when the organic light-emitting display panel does not include the touch layer 400, a preparation method described in this embodiment does not include this step. The preparation method of the touch control layer 400 can be a known method in prior art. Exemplarily, the touch layer 400 includes a touch electrode 410. The touch electrode 410 is grid-like in shape and has a plurality of grid openings 411, and the grid openings 411 have a one-to-one correspondence with the pixel openings 131. An orthographic projection of the touch electrode 410 does not overlap the orthographic projection of any one of the pixel openings 131 projected on the plane on which the array substrate 100 is located, so that the touch electrode 410 bypasses the pixel openings 131 without hindering the light of the light-emitting units 200 from being emitted out of the touch layer 400. An area of each of the grid openings 411 is larger than an area of the upper opening of the pixel opening 131 (an opening away from the array substrate 100), so that the light emitted by the light-emitting units 200 can pass through the touch layer 400 over the grid openings 411.

S4: preparing a black matrix layer 510 on a side of the thin-film encapsulation layer 300 (or the touch layer 400) away from the array substrate 100, wherein the black matrix layer 510 includes a plurality of first through holes 511 and a light-shielding portion 512 surrounding the first through holes 511, and the first through holes 511 have a one-to-one correspondence with the pixel openings 131.

Exemplarily, a material of the black matrix layer 510 is applied in a way of full-surface coating by spin coating, inkjet printing, or slit coating. A thickness of the black matrix layer 510 (i.e., a thickness of the black matrix layer 510 in the direction perpendicular to the plane on which the array substrate 100 is located) may be, for example, between 1 micron and 10 microns, and can be adjusted according to actual requirements, and light absorption characteristics of the black matrix layer 510 can be changed by adjusting a transmittance and a refractive index of the material. The first through holes 511 are formed through an exposure and development process. An opening shape, size, and an inclination angle of the side wall of the first through holes 511 can be adjusted according to actual needs. For example, the first through holes 511 and the pixel openings 131 correspond to each other in position, that is, a position of each of the first through holes 511 is located directly above one of the pixel openings 131 (taking a direction away from the array substrate 100 as a top).

S5: preparing a first organic film layer 520, so that the first organic film layer 520 is filled at least in the first through holes 511, and forming a second through hole 521 in each of the first through holes 511.

In one embodiment, step S5 includes: forming the first organic film layer 520, so that the first organic film layer 520 is filled only in the first through holes 511, and forming the second through hole 521 in each of the first through holes 511. That is, the first organic film layer 520 covers only a side wall of each of the first through holes 511 and surrounds the side wall of each of the first through holes 511 to form the second through hole 521.

In another embodiment, step S5 includes: forming the first organic film layer 520, so that the first organic film layer 520 is filled in the first through holes 511, and forming the second through hole 521 in each of the first through holes 511, and the first organic film layer 520 further covers a surface of the light-shielding portion 512 away from the array substrate 100. That is, the first organic film layer 520 covers both the side wall of each of the first through holes 511 and the surface of the light-shielding portion 512 away from the light-emitting device layer, and the first organic film layer 520 surrounds to form the second through hole 521 in each of the first through holes 511.

Exemplarily, a material of the first organic film layer 520 is applied in a way of full-surface coating by spin coating, inkjet printing, or slit coating. A thickness of the first organic film layer 520 can be adjusted according to actual requirements, wherein the first organic film layer 520 covering the side wall of the first through hole 511 has a thickness h1, for example, between 1 micron and 10 microns (i.e., a thickness in the direction perpendicular to the side wall of the first through hole 511). The first organic film layer 520 has a thickness h2, for example, between 1 micron and 10 microns (i.e., a thickness in the direction perpendicular to the plane on which the array substrate 100 is located) on a side of the light-shielding portion 512 away from the array substrate 100. The thickness h2 may be uniform thickness or non-uniform thickness. The first organic film layer 520 may be made of, for example, an optical clear adhesive. A material of the first organic film layer 520 includes, but not limited to, an organic material containing acrylic resin, epoxy resin, polyimide, polyethylene, and/or siloxane. The second through holes 521 are formed through an exposure and development process, and the first organic film layer 520 on the black matrix layer 510 may be removed at the same time, leaving only the organic film layer 520 on the side wall of each of the first through holes 511, or the first organic film layer 520 covering the side wall of each of the first through holes 511 and covering the surface of the light-shielding portion 512 away from the light-emitting device layer may also be left. The second through holes 521, for example, are corresponding to position of the pixel openings 131, that is, a position of each of the second through holes 521 is located directly above one of the pixel openings 131 (taking a direction away from the array substrate 100 as a top). It can be understood that an opening shape, size, and side wall inclination angle of the second through holes 521 can be adjusted according to actual needs. By adjusting the opening shape, size, and an inclination angle of the side wall of the second through hole 521, and the transmittance and refractive index of the first organic film layer 520, light can be reflected by the side wall of the second through hole 521, especially totally reflected, and a critical angle of the total reflection can be changed.

S6: preparing an organic planarization layer 530, so that the organic planarization layer 530 covers the black matrix layer 510 and the first organic film layer 520, and fills each of the second through holes 521.

Exemplarily, a material of the organic planarization layer 530 is applied in a way of full-surface coating by spin coating, inkjet printing, or slit coating. A thickness of the organic planarization layer 530 can be adjusted according to actual requirements, wherein the organic planarization layer 530 has a thickness h3, for example, between 5 microns and 30 microns (i.e., a thickness in the direction perpendicular to the plane on which the array substrate 100 is located) on the side of the light-shielding portion 512 away from the array substrate 100. The thickness h3 does not include the part located in the second through hole 521. The organic planarization layer 530 is made of a material including, but not limited to, organic materials, such as acrylic resin, epoxy resin, polyimide, or polyethylene and/or siloxane, or a mixed material of any one of the aforementioned organic materials and zirconia, titania, and/or alumina particles. The material of the organic planarization layer 530 is different from the material of the first organic film layer 520. The light emitted by the light-emitting units 200 is incident on the interface between the organic planarization layer 530 and the first organic film layer 520 and is reflected thereby, so that light being scattered can be gathered, thereby reducing a light scattering loss and improving light output from a forward direction of a light-emitting area of the display panel.

In one embodiment, in step S6, the organic planarization layer 530 has a refractive index being greater than a refractive index of the first organic film layer 520, which can provide conditions for total reflection of light, so that the light emitted by the light-emitting units 200 at large angles can be totally reflected by the interface between the first organic film layer 520 and the organic planarization layer 530, thereby further reducing a light loss and increasing a light output ratio. In one embodiment, the refractive index of the first organic film layer 520 is between 1.2 and 1.5, and the refractive index of the organic planarization layer 530 is between 1.7 and 2.0.

S7: preparing a color filter layer 540 on the organic planarization layer 530, and the color filter layer 540 includes a plurality of color filter units 541, wherein the color filter units 541 have a one-to-one correspondence with the first through holes 511.

Exemplarily, a color resist material is applied in a way of full-surface coating by spin coating, inkjet printing, or slit coating. A thickness of the color filter layer 540 (i.e., a thickness in the direction perpendicular to the plane on which the array substrate 100 is located) may be, for example, between 1 micron to 10 microns, and can be adjusted according to actual requirements. The color filter units 541 are formed through an exposure and development process. The color filter units 541 include a red color filter unit, a green color filter unit, and a blue color filter unit, which are configured for filtering red light, green light, and blue light, respectively. For example, the color filter units 541 are corresponding to position of the first through hole 511, respectively. That is, a position of each of the color filter units 541 is located directly above one of the first through holes 511 (taking a direction away from the array substrate 100 as a top).

In one embodiment, the preparation method of the organic light-emitting display panel in accordance with an embodiment of the present application further includes:

S8: preparing a second organic film layer 550, so that the second organic film layer 550 covers the color film layer 540. The second organic film layer 550 serves to provide a planarization effect.

Exemplarily, a material of the second organic film layer 550 is applied in a way of full-surface coating by spin coating, inkjet printing, or slit coating. A thickness of the second organic film layer 550 can be adjusted according to actual requirements, wherein the second organic film layer 550 has a thickness h4 between 5 microns and 30 microns on a side of the color filter layer 540 away from the array substrate 100 (i.e., a thickness in the direction perpendicular to the plane on which the array substrate 100 is located). The thickness h4 does not include part of the second organic film layer 550 filled in the third through hole 542. A material of the second organic film layer 550 may be, for example, an optical clear adhesive. The material of the second organic film layer 550 includes, but not limited to, an organic material containing acrylic resin, epoxy resin, polyimide, polyethylene, and/or siloxane. The second organic film layer 550 has a refractive index between 1.3 and 1.5. It should be noted that the material of the second organic film layer 550 and the material of the first organic film layer 520 may be the same or different.

For the parts that are not described in detail in the preparation method described in the embodiments of the present application, please refer to the foregoing related descriptions of the respective embodiments of the organic light-emitting display panel.

Correspondingly, an embodiment of the present application further provides a display device, which includes the organic light-emitting display panel described in any one of the above-mentioned embodiments.

The organic light-emitting display panel and the display device provided by the embodiments of the present application are described in detail above. Specific examples are used in this article to explain the principles and implementation of this application. The descriptions of the above embodiments are only used to help understand the technical solutions and core ideas of this application. Also, for those skilled in the art, according to the idea of this application, there will be changes in the specific implementation and application scope. In summary, the content of this application should not be construed as a limitation on this application.

What is claimed is:

1. An organic light-emitting display panel, comprising:
an array substrate comprising a pixel definition layer comprising a plurality of pixel openings;
a light-emitting device layer comprising a plurality of light-emitting units each disposed in one of the pixel openings;
a thin-film encapsulation layer covering the light-emitting device layer;
a black matrix layer located at a side of the thin-film encapsulation layer away from the array substrate and comprising a plurality of first through holes and a light-shielding portion surrounding the first through holes, wherein the first through holes have a one-to-one correspondence with the pixel openings;
a first organic film layer filled at least in the first through holes and allowing for formation of a second through hole in each of the first through holes;
an organic planarization layer covering the black matrix layer and the first organic film layer and filled in each of the second through holes, wherein the organic planarization layer has a refractive index greater than a refractive index of the first organic film layer; and
a color filter layer disposed on the organic planarization layer and comprising a plurality of color filter units having a one-to-one correspondence with the first through holes;
wherein an orthographic projection of each of the pixel openings and an orthographic projection of a corresponding one of the first through holes projected on a plane on which the array substate is located at least partially overlap each other, the orthographic projection of the corresponding one of the first through holes and an orthographic projection of a corresponding one of the color filter units projected on the plane on which the array substate is located at least partially overlap each other, each of the second through holes has an inverted trapezoidal shape in cross-section in a direction perpendicular to the array substrate, and an interface between the first organic film layer and the organic planarization layer in each of the second through holes is located at an angle between 40 degrees and 70 degrees with respect to a plane parallel with the array substate.

2. The display panel of claim 1, wherein the orthographic projection of each of the pixel openings and the orthographic projections of the corresponding one of the first through holes and the corresponding one of the color filter units projected on the plane on which the array substate is located completely overlap each other.

3. The display panel of claim 1, wherein the refractive index of the first organic film layer is between 1.2 and 1.5, and the refractive index of the organic planarization layer is between 1.7 and 2.0.

4. The display panel of claim 1, wherein the first organic film layer covers a surface of the light-shielding portion away from the array substrate.

5. The display panel of claim 1, wherein the first organic film layer has a thickness between 1 micron and 10 microns in a direction perpendicular to a side wall of the first through holes, and the organic planarization layer has a thickness between 5 microns and 30 microns on a side of the light-shielding portion away from the array substrate.

6. The display panel of claim 1, wherein the organic light-emitting display panel further comprises a second organic film layer covering the color filter layer, and the second organic film layer has a refractive index between 1.3 and 1.5.

7. The display panel of claim 1, wherein the organic light-emitting display panel further comprises a touch layer disposed between the thin-film encapsulation layer and the black matrix layer, wherein the touch layer comprises a touch electrode being grid-like in shape and having a plurality of grid openings, and the grid openings have a one-to-one correspondence with the pixel openings.

8. The display panel of claim 7, wherein an orthographic projection of the touch electrode does not overlap the orthographic projection of any one of the pixel openings projected on the plane on which the array substrate is located.

9. An organic light-emitting display panel, comprising:
an array substrate comprising a pixel definition layer comprising a plurality of pixel openings:
a light-emitting device layer comprising a plurality of light-emitting units each disposed in one of the pixel openings;
a thin-film encapsulation layer covering the light-emitting device layer;
a black matrix layer located at a side of the thin-film encapsulation layer away from the array substrate and comprising a plurality of first through holes and a light-shielding portion surrounding the first through holes, wherein the first through holes have a one-to-one correspondence with the pixel openings;
a first organic film layer filled at least in the first through holes and allowing for formation of a second through hole in each of the first through holes;
an organic planarization layer covering the black matrix layer and the first organic film layer and filled in each of the second through holes, wherein the organic planarization layer has a refractive index greater than a refractive index of the first organic film layer; and
a color filter layer disposed on the organic planarization layer and comprising a plurality of color filter units having a one-to-one correspondence with the first through holes.

10. The display panel of claim 9, wherein an orthographic projection of each of the pixel openings and an orthographic projection of a corresponding one of the first through holes projected on a plane on which the array substate is located at least partially overlap each other, and the orthographic projection of the corresponding one of the first through holes and an orthographic projection of a corresponding one of the color filter units projected on the plane on which the array substate is located at least partially overlap each other.

11. The display panel of claim 10, wherein the orthographic projection of each of the pixel openings and the orthographic projections of the corresponding one of the first through holes and the corresponding one of the color filter units projected on the plane on which the array substate is located completely overlap each other.

12. The display panel of claim 9, wherein the refractive index of the first organic film layer is between 1.2 and 1.5, and the refractive index of the organic planarization layer is between 1.7 and 2.0.

13. The display panel of claim 9, wherein each of the second through holes has an inverted trapezoidal shape in cross-section in a direction perpendicular to the array substrate.

14. The display panel of claim 13, wherein an interface between the first organic film layer and the organic planarization layer in each of the second through holes is located at an angle between 40 degrees and 70 degrees with respect to a plane parallel with the array substate.

15. The display panel of claim 9, wherein the first organic film layer covers a surface of the light-shielding portion away from the array substrate.

16. The display panel of claim 9, wherein the first organic film layer has a thickness between 1 micron and 10 microns in a direction perpendicular to a side wall of the first through holes, and the organic planarization layer has a thickness between 5 microns and 30 microns on a side of the light-shielding portion away from the array substrate.

17. The display panel of claim 9, wherein the organic light-emitting display panel further comprises a second organic film layer covering the color filter layer, and the second organic film layer has a refractive index between 1.3 and 1.5.

18. The display panel of claim 9, wherein the organic light-emitting display panel further comprises a touch layer disposed between the thin-film encapsulation layer and the black matrix layer, wherein the touch layer comprises a plurality of touch electrodes in a grid shape having a plurality of grid openings, and the grid openings have a one-to-one correspondence with the pixel openings.

19. The display panel of claim 18, wherein an orthographic projection of each of the touch electrodes does not overlap an orthographic projection of any one of the pixel openings projected on a plane on which the array substrate is located.

20. A display device comprising the display panel of claim 9.
